(19) United States
(12) Patent Application Publication
(10) Pub. No.: US 2021/0391151 A1
(43) Pub. Date: Dec. 16, 2021

(54) EDGE RING AND PLASMA PROCESSING APPARATUS

(71) Applicant: Tokyo Electron Limited, Tokyo (JP)

(72) Inventor: Masashi Ikegami, Kurokawa-gun (JP)

(21) Appl. No.: 17/337,536

(22) Filed: Jun. 3, 2021

(30) Foreign Application Priority Data
Jun. 12, 2020 (JP) 2020-102486
Apr. 28, 2021 (JP) 2021-075859

(51) Int. Cl. H01J 37/32; H01L 21/687; H01L 21/683; B08B 7/00

(52) U.S. Cl. CPC H01J 37/32642; H01J 37/32862; H01L 21/68721; H01J 2237/2007; B08B 7/0035; H01J 2237/335; H01J 37/32715; H01L 21/6831

(57) ABSTRACT

An edge ring disposed on a placing table to surround a processing target object placed on a placing surface of the placing table includes a first ring portion having a front surface located at a position lower than the placing surface; and a second ring portion, provided at an outer side than the first ring portion in a diametrical direction thereof, having a front surface located at a position higher than the placing surface. The front surface of the first ring portion has an irregularity.

### CROSS-REFERENCE TO RELATED APPLICATION

This application claims the benefit of Japanese Patent Application Nos. 2020-102486 and 2021-075859 filed on Jun. 12, 2020 and Apr. 28, 2021, respectively, the entire disclosures of which are incorporated herein by reference.

### TECHNICAL FIELD

The various aspects and embodiments described herein pertain generally to an edge ring and a plasma processing apparatus.

### BACKGROUND

Patent Document 1 describes a substrate processing apparatus having an electrostatic chuck configured to attract a substrate electrostatically and a focus ring provided at a peripheral portion of the electrostatic chuck to surround a circumferential portion of the substrate. In the plasma processing apparatus, a plasma processing is performed on a wafer.

Patent Document 1: Japanese Patent Laid-open Publication No. 2017-050509

### SUMMARY

In one exemplary embodiment, an edge ring disposed on a placing table to surround a processing target object placed on a placing surface of the placing table includes a first ring portion having a front surface located at a position lower than the placing surface; and a second ring portion, provided at an outer side than the first ring portion in a diametrical direction thereof, having a front surface located at a position higher than the placing surface. The front surface of the first ring portion has an irregularity.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1A and FIG. 1B are explanatory diagrams illustrating states in which a reaction product (deposit) adheres to an electrostatic chuck and an edge ring in a conventional plasma processing apparatus;

FIG. 2 is a longitudinal cross sectional view illustrating a schematic configuration of a plasma processing apparatus according to an exemplary embodiment;

FIG. 3 is a longitudinal cross sectional view illustrating a schematic configuration of a part of an electrostatic chuck and a part of an edge ring according to the exemplary embodiment;

FIG. 4 is a plan view illustrating the schematic configuration of the electrostatic chuck and the edge ring according to the exemplary embodiment;

FIG. 5 is an explanatory diagram illustrating a flow of a deposit in a conventional comparative example;

FIG. 6 is an explanatory diagram illustrating a flow of a deposit in the exemplary embodiment;

FIG. 7 is a longitudinal cross sectional view illustrating a schematic configuration of a part of an electrostatic chuck and a part of an edge ring according to another exemplary embodiment;

FIG. 8 is a plan view illustrating the schematic configuration of the electrostatic chuck and the edge ring according to the another exemplary embodiment; and

FIG. 9 is a longitudinal cross sectional view illustrating a schematic configuration of a part of an electrostatic chuck and a part of an edge ring according to yet another exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In a manufacturing process for a semiconductor device, a plasma processing is performed on a semiconductor wafer (hereinafter, referred to as “wafer”). In the plasma processing, plasma is formed by exciting a processing gas, and the wafer is processed by this plasma.

The plasma processing is performed by a plasma processing apparatus. The plasma processing apparatus generally includes a chamber, a placing table, and a high frequency (RF: Radio Frequency) power supply. As an example, the high frequency power supply includes a first high frequency power supply and a second high frequency power supply. The first high frequency power supply is configured to supply a first high frequency power to form plasma of a gas within the chamber. The second high frequency power supply is configured to supply a second high frequency bias power to attract ions into the wafer. An internal space of the chamber is configured as a processing space in which the plasma is formed. The placing table is provided within the chamber. The placing table includes a lower electrode and an electrostatic chuck. The electrostatic chuck is provided on the lower electrode. An edge ring is disposed on the electrostatic chuck to surround the wafer placed on the electrostatic chuck. The edge ring is configured to improve uniformity of the plasma processing upon the wafer.

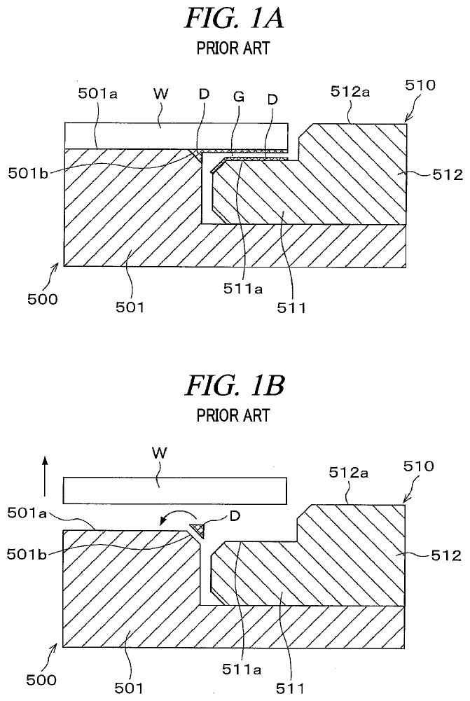

To elaborate, a positional relationship between the electrostatic chuck, the wafer placed on the electrostatic chuck and the edge ring is as described in, for example, Patent Document 1. That is, as illustrated in FIG. 1A and FIG. 1B, a central portion 501 of an electrostatic chuck 500 has a diameter smaller than a diameter of a wafer W. Accordingly, when the wafer W is placed on a wafer placing surface 501a of the electrostatic chuck 500, a circumferential portion of the wafer W is protruded from the central portion 501 of the electrostatic chuck 500. An edge ring 510 is disposed to surround the wafer W placed on the wafer placing surface 501a. The edge ring 510 has a step shape, and a front surface 511a of a first ring portion at an inner peripheral side is lower than the wafer placing surface 501a, and a surface 512a of a second ring portion 512 at an outer peripheral side is higher than the wafer placing surface 501a. That is, the first ring portion 511 is formed to be located under the circumferential portion of the wafer W which is protruded from the central portion 501 of the electrostatic 500.

In the plasma processing, a reaction product D (deposit D) enters a gap G surrounded by the wafer W, the electrostatic chuck 500 and the edge ring 510, ending up being attached to the electrostatic chuck 500 and the edge ring 510, as depicted in FIG. 1A. At this time, in the electrostatic chuck 500, the deposit D adheres to a chamfered upper end edge 501b of the central portion 501. Further, in the edge ring 510, the deposit D adheres to the front surface 511a of the first ring portion 511.

By way of example, if temperatures of the electrostatic chuck 500 and the edge ring 510 are same, an adhesion amount of the deposit D depends on a horizontal distance from the circumferential portion of the wafer W. That is, in this case, the deposit D having entered the gap G first adheres to the front surface 511a of the first ring portion 511, so the adhesion amount of the deposit D to the upper end edge 501b is smaller.

Since, however, the electrostatic chuck 500 is cooled by a coolant as will be described later, it has a low temperature. Meanwhile, since the edge ring 510 is exposed to the plasma, it has a temperature higher than the temperature of the electrostatic chuck 500. Since the deposit D tends to easily adhere to whichever has a lower temperature, the deposit D adheres to the upper end edge 501b more. Besides, the deposit D once attached to the upper end edge 501b is difficult to remove.

Afterwards, upon the completion of the plasma processing, when the wafer W is raised from the electrostatic chuck 500 to be taken out, the deposit D attached to the upper end edge 501b may be peeled off due to a stress or the like. If the peeled deposit D adheres to the wafer placing surface 501a of the electrostatic chuck 500, it may cause an attraction failure of the wafer W to the electrostatic chuck 500.

Here, upon the completion of the plasma processing upon a required number of wafers W, the deposit D is removed by performing dry-cleaning on the electrostatic chuck 500 and the edge ring 510 in the state that no wafer W is placed on the placing table. For example, in this dry-cleaning, plasma is formed to excite an oxygen gas to remove the deposit D. Here, however, although the deposit D attached to the edge ring 510 can be removed by the dry-cleaning as the edge ring 510 has the high temperature, the deposit D adhering to the upper end edge 501b may not be completely removed by the dry-cleaning as the temperature of the electrostatic chuck 500 is low. As a result, there is still a high likelihood that the deposit D attached to the upper end edge 501b may be peeled off when the wafer W is carried out, as stated above.

Further, recently, it is required to improve MTBC (Mean Time Between Cleaning), that is, a mean time from a current cleaning processing to a next cleaning processing in the plasma processing apparatus. In improving the MTBC, the cleaning of the deposit D attached to the upper end edge 501b of the electrostatic chuck 500 is a big issue. That is, if this cleaning time can be reduced, a throughput can be improved, and a consumption of the components of the plasma processing apparatus can be reduced, resulting in a further increase of the MTBC.

The present disclosure provides a technique capable of suppressing the reaction product (deposit) from being attached to the circumferential portion of the placing surface of the placing table on which the processing target object is placed (that is, the upper end edge of the electrostatic chuck). Hereinafter, a plasma processing apparatus and an edge ring according to the present exemplary embodiment will be described with reference to the accompanying drawings. In the present specification and drawings, parts having substantially same functions and configurations will be assigned same reference numerals, and redundant description will be omitted.

<Plasma Processing Apparatus>

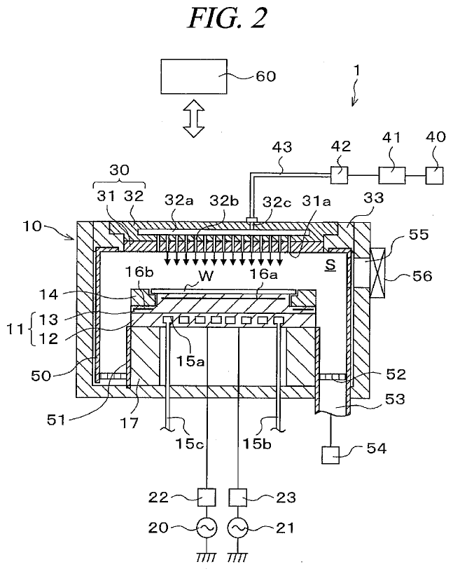

First, the plasma processing apparatus according to the exemplary embodiment will be described. FIG. 2 is a longitudinal cross sectional view illustrating a schematic configuration of a plasma processing apparatus 1. The plasma processing apparatus 1 is a capacitively coupled plasma processing apparatus. In the plasma processing apparatus 1, a plasma processing is performed on a wafer W as a processing target object. As the plasma processing, an etching processing, a film forming processing, a diffusing processing, or the like is performed, though not particularly limited thereto.

As depicted in FIG. 2, the plasma processing apparatus 1 has a substantially cylindrical chamber 10. The chamber 10 has therein a processing space S in which plasma is formed. The chamber 10 is made of, by way of non-limiting example, aluminum. The chamber 10 is grounded to have a ground potential. A film having plasma resistance is formed on an inner wall surface of the chamber 10, that is, on a wall surface confining the processing space S. This film may be a film formed by anodic oxidation or a ceramic film such as one formed of yttrium oxide.

A placing table 11 configured to place the wafer W thereon is accommodated in the chamber 10. The placing table 11 has a lower electrode 12 and an electrostatic chuck 13. Further, an edge ring 14 is provided on the placing table 11 to surround the wafer W placed on the placing table 11. Further, an electrode plate (not shown) made of, by way of example, aluminum may be provided on a bottom surface of the lower electrode 12.

The lower electrode 12 is made of a conductive metal, for example, aluminum, and has a substantially disk shape.

A coolant path 15a is formed within the lower electrode 12. A coolant from a chiller unit (not shown) provided at an outside of the chamber 10 is supplied into the coolant path 15a through a coolant inlet line 15b. The coolant introduced into the coolant path 15a is returned back into the chiller unit through a coolant outlet line 15c. By circulating the coolant, for example, cooling water in the coolant path 15a, the electrostatic chuck 13, the edge ring 14 and the wafer W can be cooled to have a required temperature.

The electrostatic chuck 13 is provided on the lower electrode 12. The electrostatic chuck 13 is a member configured to be capable of attracting and holding both the wafer W and the edge ring 14 by an electrostatic force. The electrostatic chuck 13 is formed such that a top surface of a central portion thereof is higher than a top surface of a peripheral portion thereof. The top surface of the central portion of the electrostatic chuck 13 serves as a wafer placing surface on which the wafer W is placed, and the top surface of the peripheral portion of the electrostatic chuck 13 serves as an edge ring placing surface on which the edge ring 14 is placed. Further, details of the configuration of the electrostatic chuck 13 will be described later.

A first electrode 16a configured to attract and hold the wafer W is provided at the central portion within the electrostatic chuck 13. A second electrode 16b configured to attract and hold the edge ring 14 is provided at the peripheral portion within the electrostatic chuck 13. The electrostatic chuck 13 has a structure in which the electrodes 16a and 16b are embedded in an insulating member made of an insulating material.

A DC voltage from a DC power supply (not shown) is applied to the first electrode 16a to generate an electrostatic force. The wafer W is attracted to and held on the top surface of the central portion of the electrostatic chuck 13 by this electrostatic force. Likewise, a DC voltage from the DC power supply (not shown) is applied to the second electrode 16b to generate an electrostatic force. The edge ring 14 is attracted to and held on the top surface of the peripheral portion of the electrostatic chuck 13.

The edge ring 14 is an annular member disposed to surround the wafer W placed on the placing surface at the central portion of the electrostatic chuck 13. The edge ring 14 is configured to improve uniformity of the plasma processing. For the purpose, the edge ring 14 is made of a material appropriately selected depending on the plasma processing involved. By way of non-limiting example, the edge ring 14 is made of quartz, Si, SiC, or the like. Details of the of this edge ring 14 will be elaborated later.

The placing table 11 having the above-described configuration is provided on a substantially cylindrical supporting member 17 provided at a bottom of the chamber 10. The supporting member 17 is made of an insulator such as, but not limited to, ceramic or quartz.

Further, though not shown, the placing table 11 may include a temperature control module configured to regulate at least one of the placing table 11, the electrostatic chuck 13, the edge ring 14 and the wafer W to a required temperature. The temperature control module may include a heater, a path or a combination thereof. A temperature control fluid such as a coolant or a heat transfer gas flows in the path.

The plasma processing apparatus 1 is further equipped with a first high frequency (RF: Radio Frequency) power supply 20, a second high frequency power supply 21, a first matching device 22 and a second matching device 23. The first high frequency power supply 20 and the second high frequency power supply 21 are connected to the lower electrode 12 via the first matching device 22 and the second matching device 23, respectively.

The first high frequency power supply 20 is a power supply configured to generate a high frequency power HF for plasma formation. The high frequency power HF having a frequency ranging from 27 MHz to 100 MHz, for example, 40 MHz is supplied to the lower electrode 12 from the first high frequency power supply 20. The first matching device 22 has a circuit configured to match an output impedance of the first high frequency power supply 20 and an input impedance at a load side (lower electrode 12 side). Further, the first high frequency power supply 20 may not be electrically connected to the lower electrode 12 but be connected via the first matching device 22 to the shower head 30 serving as an upper electrode.

The second high frequency power supply 21 is configured to generate a high frequency power LF for ion attraction into the wafer W (i.e., high frequency bias power), and apply this generated high frequency power LF to the lower electrode 12. A frequency of the high frequency power LF may be in a range from 400 kHz to 13.56 MHz, for example, 400 kHz. The second matching device 23 is a circuit configured to match an output impedance of the second high frequency power supply 21 and an input impedance at a load side (lower electrode 12 side). Further, a DC pulse generator may be used instead of the second high frequency power supply 21.

A shower head 30 is provided above the placing table 11, facing the placing table 11. The shower head 30 includes an electrode plate 31 disposed to be in direct contact with the processing space S, and an electrode supporting body 32 disposed on top of the electrode plate 31. The electrode plate 31 serves as the upper electrode which is in pair with the lower electrode 12. As will be described later, if the first high frequency power supply 20 is electrically connected to the lower electrode 12, the shower head 30 is connected to the ground potential. Further, the shower head 30 is supported at an upper portion (ceiling surface) of the chamber 10 with an insulating shield member 33 therebetween.

The electrode plate 31 is provided with a multiple number of gas discharge openings 31a through which a processing gas introduced from a gas diffusion space 32a to be described later is supplied into the processing space S. The electrode plate 31 is made of, by way of non-limiting example, a low-resistance conductor or semiconductor having a small Joule heat.

The electrode supporting body 32 is configured to support the electrode plate 31 in a detachable manner. The electrode supporting body 32 has a structure in which a plasma-resistance film is formed on a surface of a conductive material such as, but not limited to, aluminum. This film may be a film formed by anodic oxidation or a ceramic film such as one formed of yttrium oxide. The gas diffusion space 32a is formed within the electrode supporting body 32. A multiple number of gas holes 32b are extended from the gas diffusion space 32a to communicate with the gas discharge openings 31a, respectively. Further, a gas inlet hole 32c connected to a gas supply line 43 to be described later is formed at the gas diffusion space 32a.

Furthermore, a gas source group configured to supply the processing gas into the gas diffusion space 32a is connected to the electrode supporting body 32 via a flow rate controller group 41, a valve group 42, the gas supply line 43 and the gas inlet hole 32c.

The gas source group 40 includes multiple kinds of gas sources required for the plasma processing. The flow rate controller group 41 includes a plurality of flow rate controllers, and the valve group 42 includes a plurality of valves. Each of the plurality of flow rate controllers belonging to the flow rate controller group 41 is a mass flow controller or a pressure control type flow rate controller. In the plasma processing apparatus 1, a processing gas from one or more gas sources selected from the gas source group 40 is supplied into the gas diffusion space 32a via the flow rate controller group 41, the valve group 42, the gas supply line 43 and the gas inlet hole 32c. The processing gas introduced into the gas diffusion space 32a is supplied into the processing space S through the gas discharge openings 31a while being distributed in a shower shape.

In the plasma processing apparatus 1, a deposition shield 50 is provided along an inner wall of the chamber 10 in a detachable manner. The deposition shield 50 is configured to suppress a deposit from adhering to the inner wall of the chamber 10. By way of non-limiting example, the deposition shield 50 is prepared by coating ceramic such as yttrium oxide on an aluminum member. Likewise, a deposition shield 51 is detachably provided on an outer side surface of the supporting member 17 which is a surface facing the deposition shield 50.

At the bottom of the chamber 10, a baffle plate 52 is provided between the inner wall of the chamber 10 and the supporting member 17. The baffle plate 52 is configured as, for example, an aluminum member coated with ceramic such as yttrium oxide. The baffle plate 52 is provided with a plurality of through holes. The processing space S communicates with an exhaust port 53 via the baffle plate 52. An exhaust device 54 such as, but not limited to, a vacuum pump is connected to the exhaust port 53, and the inside of the processing space S can be decompressed by the exhaust device 54.

Furthermore, a carry-in/out opening 55 for the wafer W is provided at a sidewall of the chamber 10, and this carry-in/out opening 55 is opened or closed by a gate valve 56.

The above-described plasma processing apparatus 1 is equipped with a controller 60. The controller 60 is, for example, a computer having a CPU, a memory, and so forth. This controller 60 has a program storage (not shown). The program storage stores therein a program for controlling the plasma processing in the plasma processing apparatus 1. Further, this program may be recorded on a computer-readable recording medium and installed from this recording medium to the controller 60.

<Plasma Processing Method>

Now, the plasma processing performed by using the plasma processing apparatus 1 configured as described above will be explained.

First, the wafer W is carried into the chamber 10 and placed on the electrostatic chuck 13. Then, by applying the DC voltage to the first electrode 16a of the electrostatic chuck 13, the wafer W is electrostatically attracted to and held by the electrostatic chuck 13 by a Coulomb force. Further, after the wafer W is carried in, the inside of the chamber 10 is decompressed to a required vacuum level by the exhaust device 54.

Next, the processing gas is supplied from the gas source group 40 into the processing space S through the shower head 30. Further, the high frequency power HF for plasma formation is supplied to the lower electrode 12 by the first high frequency power 20 to excite the processing gas, so that plasma is formed. At this time, the high frequency power LF for ion attraction may also be supplied by the second high frequency power supply 21. The plasma processing is performed on the wafer W by the formed plasma.

To end the plasma processing, the supply of the high frequency power HF from the first high frequency power supply 20 and the supply of the processing gas from the gas source group 40 are first stopped. Further, in case that the high frequency power LF is supplied during the plasma processing, the supply of this high frequency power LF is also stopped. Then, the supply of the heat transfer gas to the rear surface of the wafer W is stopped, and the attracting/holding of the wafer W by the electrostatic chuck 13 is stopped.

Thereafter, the wafer W is carried out of the chamber 10, and the plasma processing upon the wafer W including the aforementioned series of processes is completed.

Here, in the plasma processing, the plasma may be formed by using only the high frequency power LF from the second high frequency power supply 21 without using the high frequency power HF from the first high frequency power supply 20.

<Electrostatic Chuck and Edge Ring>

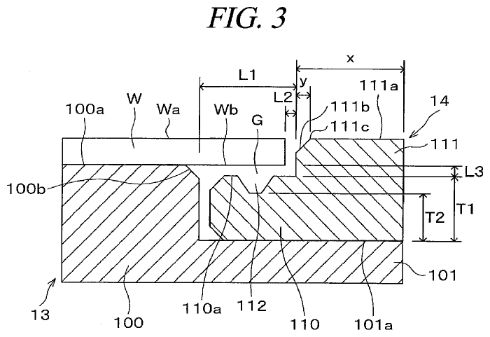

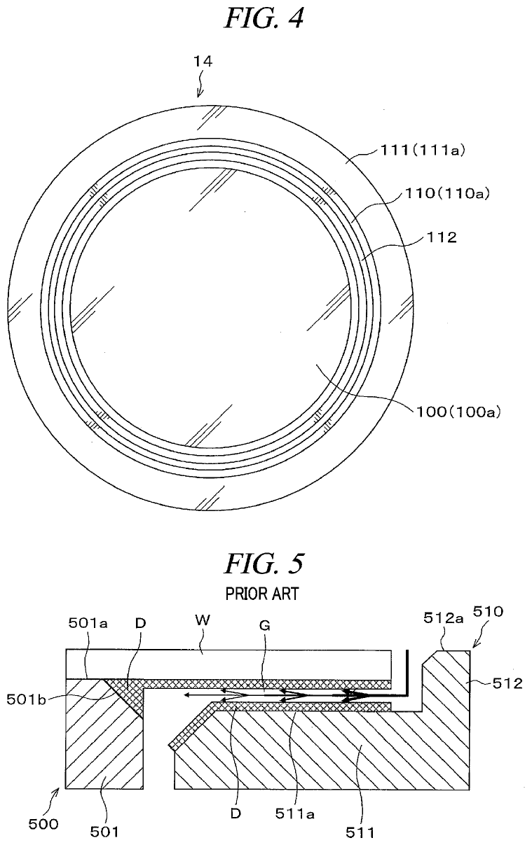

Now, a main configuration of the electrostatic chuck 13 and the edge ring 14 will be discussed. FIG. 3 is a longitudinal cross sectional view illustrating a schematic configuration of a part of the electrostatic chuck 13 and a part of the edge ring 14. FIG. 4 is a plan view illustrating the schematic configuration of the electrostatic chuck 13 and the edge ring 14.

The electrostatic chuck 13 includes a central portion 100 and a peripheral portion 101 formed as one body. The central portion 100 has a wafer placing surface 100a on which the wafer W is placed, and the peripheral portion 101 has an edge ring placing surface 101a on which the edge ring 14 is placed. The central portion 100 is protruded from the peripheral portion 101, and the wafer placing surface 100a of the central portion 100 is higher than the edge ring placing surface 101a of the peripheral portion 101. In the central portion 100, an edge portion of the wafer placing surface 100a is chamfered in a ring shape, forming an upper end edge 100b.

The central portion 100 of the electrostatic chuck 13 has a diameter smaller than, for example, a diameter of the wafer W, so when the wafer W is placed on the wafer placing surface 100a, the circumferential portion of the wafer W is protruded from the central portion 100 of the electrostatic chuck 13.

Further, although the central portion 100 and the peripheral portion 101 of the electrostatic chuck 13 according to the present exemplary embodiment is formed as one body, the central portion 100 and the peripheral portion 101 may be configured as separate bodies.

The edge ring 14 is disposed to surround the wafer W placed on the wafer placing surface 100a. The edge ring 14 includes a first ring portion 110 having an annular shape and a second ring portion 111 having an annular shape which are formed as one body. The first ring portion 110 and the second ring portion 111 are concentrically arranged, and the second ring portion 111 is provided at an outer side than the first ring portion 110 in a diametrical direction thereof.

A front surface 110a of the first ring portion 110 is lower than the wafer placing surface 100a. A front surface 111a of the second ring portion 111 is higher than the wafer placing surface 100a, and is on a level with or higher than a front surface Wa of the wafer W placed on the wafer placing surface 100, for example. That is, an inner circumferential end of the second ring portion 111 is chambered a lot. That is, the second ring portion 111 is provided with an upper end inner circumferential portion 111b having a taper shape. A ratio of the upper end inner circumferential portion 111b (a ratio between a length x from the inner circumferential end to an outer circumferential end of the second ring portion 111 and a length y from the inner circumferential end of the second ring portion 111 to a taper end 111c of the upper end inner circumferential portion 111b) is, for example, about 10%. Further, an inner diameter of the first ring portion 110 is larger than the diameter of the central portion 100 and smaller than the diameter of the wafer W. An inner diameter of the second ring portion 111 is larger than the diameter of the wafer W. The first ring portion 110 is disposed to be located under the circumferential portion of the wafer W protruded from the central portion 100 of the electrostatic chuck 13.

The front surface 110a of the first ring portion 110 has irregularities. That is, a groove 112 is formed on the front surface 110a. The groove 112 is annularly formed along an entire circle concentric with the first ring portion 110. The groove 112 is provided under the wafer W placed on the wafer placing surface 100a. That is, the groove 112 is provided at a position where it is overlapped with the wafer W when viewed from the top.

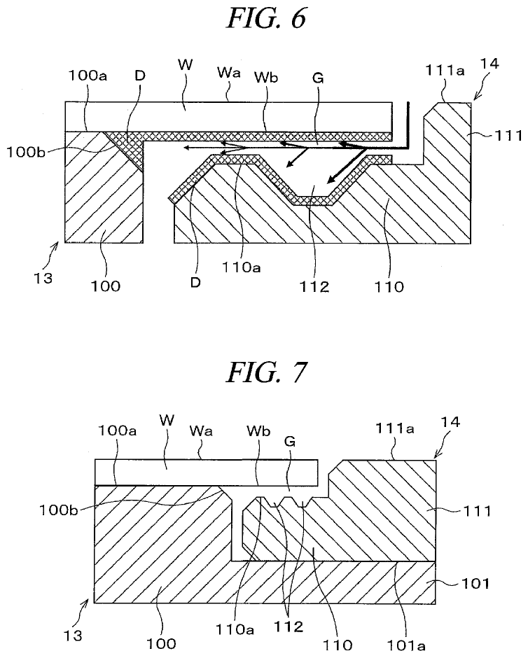

The groove 112 is provided to control adhesion of a reaction product D (deposit D) generated by the plasma processing. That is, due to the presence of the groove 12, the deposit D is allowed to adhere to the front surface 110a of the first ring portion 110, so that the deposit D is suppressed from being attached to the upper end edge 100b of the electrostatic chuck 113. Hereinafter, the function of this groove 112 will be explained. FIG. 5 is an explanatory diagram illustrating a flow of the deposit D in a conventional comparative example. FIG. 6 is an explanatory diagram illustrating a flow of the deposit D in the present exemplary embodiment.

First, the comparative example using the conventional edge ring 510 will be explained. As shown in FIG. 5, in the comparative example, the front surface 511a of the first ring portion 511 is flat and is not provided with the groove 112 as in the present exemplary embodiment. In the plasma processing, the deposit D enters the gap G surrounded by the wafer W, the electrostatic chuck 500 and the edge ring 510 from a gap between the circumferential portion of the wafer W and the second ring portion 512. A part of this deposit D adheres to the front surface 511a of the first ring portion 511, and the rest of the deposit D reaches the electrostatic chuck 500 to adhere to the upper end edge 501b.

Further, since the electrostatic chuck 500 is cooled by a coolant flowing in a coolant path, it has a low temperature. The temperature of the electrostatic chuck 500 is, for example, equal to or less than 90° C. though it differs depending on processing conditions. Meanwhile, although the edge ring 510 is also cooled by the coolant, it has a temperature higher than that of the electrostatic chuck 500 as it is exposed to the plasma. The temperature of the edge ring 510 is, for example, equal to or higher than 170° C. though it also differs depending on processing conditions. Since the deposit D tends to be attached to whichever has a lower temperature, the deposit D adheres to the upper end edge 501b of the electrostatic chuck 500 a lot. Besides, the deposit D attached to the upper end edge 501b is difficult to remove.

Meanwhile, the front surface 110a of the first ring portion 110 of the edge ring 14 according to the present exemplary embodiment is provided with the groove 112. As shown in FIG. 6, the deposit D having entered the gap G also adheres to an inner surface of the groove 112. Accordingly, as compared to the comparative example shown in FIG. 5, more deposit D adheres to the front surface 110a. That is, since the groove 112 is recessed from the front surface 110a, a surface area of the first ring portion 110 increases. As much as this surface area increases, more deposit D adheres to the front surface 110a before the deposit D attaches to the upper end edge 100b of the electrostatic chuck 13. For example, when a total amount of the deposit D which enters the gap G is same in the comparative example and the present exemplary embodiment, an adhesion amount of the deposit D adhering to the front surface 110a of the first ring portion 110 is larger in the present exemplary embodiment than in the comparative example. Thus, an adhesion amount of the deposit D attached to the upper end edge 100b of the electrostatic chuck 13 can be reduced.

Further, the portion of the first ring portion 110 where the groove 112 is provided has a thickness smaller than that of the rest of the first ring portion 110. The first ring portion 110 having the reduced thickness due to the presence of the groove 112 is easily cooled by the coolant in the coolant path 15a. As a result, the deposit D is easily attached to the groove 112. From this perspective as well, the adhesion amount of the deposit D attached to the front surface 110a is increased, so that the adhesion amount of the deposit D adhering to the upper end edge 100b can be reduced.

As stated above, according to the present exemplary embodiment, since the groove 112 is provided on the front surface 110a of the first ring portion 110, the adhesion amount of the deposit D attached to the front surface 110a in the plasma processing can be increased, so that the adhesion amount of the deposit D adhering to the upper end edge 100b of the electrostatic chuck 13 can be reduced. As a result, the deposit D is suppressed from being peeled off the upper end edge 100b and ending up being attached to the wafer placing surface 100a. Therefore, the attraction failure of the wafer W to the electrostatic chuck 13 can be suppressed.

Further, since the adhesion amount of the deposit D adhering to the upper end edge 100b can be reduced, a frequency of cleaning of the electrostatic chuck 13 can be reduced. As a result, a throughput of the wafer processing can be improved. Further, since the groove 12 is not exposed to the plasma, the consumption of the edge ring 14 that might be caused by the wear-out of the groove 14 can be suppressed, so that the MTBC can be increased.

Here, as a measure to suppress the adhesion of the deposit D to the upper end edge 100b, it may be considered to change the shape of the electrostatic chuck 13, reduce the temperature of the edge ring 14, or the like. By way of example, when changing the shape of the electrostatic chuck 13, it may be considered to reduce the diameter of the central portion 100 of the electrostatic chuck 13, thus rendering it difficult for the deposit D to reach the upper end edge 100b. If, however, the shape of the electrostatic chuck 13 is changed, it has a large influence upon the plasma processing (process). For example, it affects the cooling of the wafer W or the supply of the high frequency power greatly. Further, when reducing the temperature of the edge ring 14 as well, it may have an influence upon the plasma processing of the circumferential portion of the wafer W.

According to the present exemplary embodiment, however, only the groove 112 is formed on the front surface 110a of the first ring portion 110, and this groove 112 is provided under the wafer W not to be exposed to the plasma. Therefore, the influence upon the plasma processing (process) can be suppressed. Besides, since the temperature of the edge ring 14 can be set as required, the influence upon the plasma processing can also be suppressed.

To suppress the deposit D attached to the upper end edge 100b of the electrostatic chuck 13 to achieve the effects of the present exemplary embodiment as described above, the surface area of the first ring portion 110 needs to be increased. For the purpose, it is desirable that a depth of the groove 12 is large. From a restriction in the structure of the first ring portion 110, however, if a thickness T1 of the first ring portion 110 is 1.5 mm, a thickness T2 of the portion of the first ring portion 110 where the groove 112 is provided is in a range from 0.7 mm to 0.8 mm, as shown in FIG. 3, for example.

Further, as illustrated in FIG. 3, a distance L1 between an outer vertical surface of the central portion 100 of the electrostatic chuck 13 and an inner vertical surface of the second ring portion 111 is in a range from, e.g., 2.0 mm to 2.5 mm. A distance L2 between the circumferential portion of the wafer W and the inner vertical surface of the second ring portion 11 is, for example, 0.5 mm. A distance L3 between the wafer placing surface 100a (rear surface Wb of the wafer W) of the central portion 100 and the front surface 110a of the first ring portion 110, that is, a height of the gap G is, for example, 0.1 mm.

Further, in order to increase the surface area of the first ring portion 110, a plurality of annular grooves 112 may be formed on the front surface 110a in the diametrical direction, as shown in FIG. 7. Though two grooves 112 are provided in the shown example, the number of the grooves 112 is not limited thereto and may be more than two.

Furthermore, although the groove 112 has a substantially trapezoidal cross sectional shape in the present exemplary embodiment, the present exemplary embodiment is not limited thereto. By way of non-limiting example, the groove 112 may have a rectangular cross sectional shape. If, however, convenience in forming the groove 112 on the front surface 110a is taken into account, it is desirable that the groove 112 has the substantially trapezoidal cross sectional shape.

Moreover, in the present exemplary embodiment, though the groove 112 is formed on the front surface 110a along the entire circumference thereof, the groove 112 may be provided at a part of it.

In addition, in the present exemplary embodiment, the groove 112 is provided under the wafer W placed on the wafer placing surface 100a. However, a position on the front surface 110a where the groove 112 is provided is not particularly limited. The groove 112 may be provided near the second ring portion 111 or near the electrostatic chuck 13 as long as it is located under the wafer W. If, however, an influence of the plasma formed by the plasma processing upon the wafer W is taken into account, it is desirable to provide the groove 112 near the second ring portion 111.

Further, the groove 112 may be provided at an outside of the wafer W placed on the wafer placing surface 100a, i.e., to be exposed to a gap between the circumferential portion of the wafer W and an inner side surface of the second ring portion 111 when viewed from the top. In this configuration, however, there is a likelihood that the plasma enters the groove 112. Thus, in consideration of the influence upon the plasma processing, it is desirable to provide the groove 112 under the wafer W.

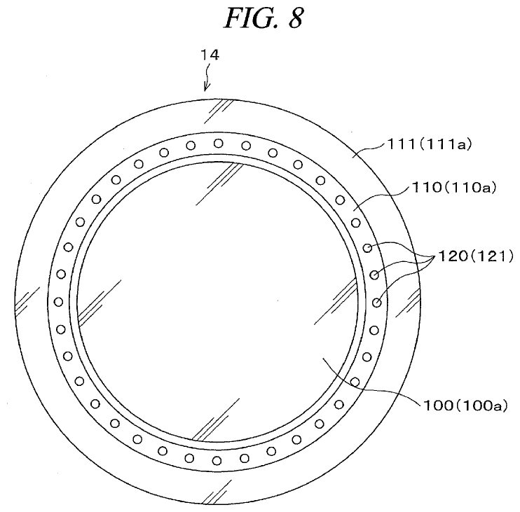

Additionally, in the present exemplary embodiment, the irregularities are formed on the front surface 110a by providing the groove 112 thereon. However, the way how to form the irregularities is not limited thereto. By way of example, the front surface 110a may be roughened. Further, as depicted in FIG. 8, a multiple number of dots 129 (a plurality of protrusions) may be provided on the front surface 110a, or a multiple number of dimples 121 (a plurality of recesses) may be provided on the front surface 110a. Besides, in the example of FIG. 8, though these dots 120 or dimples 121 have a substantially circular shape when viewed from the top, the shape of the dots 120 or the dimples 121 is not limited thereto.

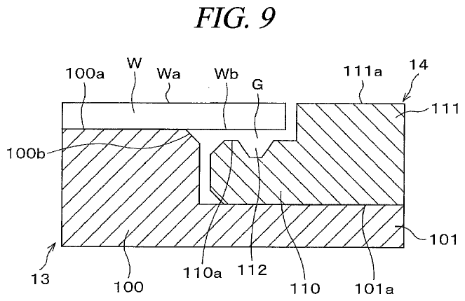

Further, in the present exemplary embodiment, the taper-shaped upper end edge 111b is formed by largely chamfering the inner peripheral side of the surface 111a of the second ring portion 111 of the edge ring 14 in the ring shape. However, this upper end edge 111b may be omitted. That is, as shown in FIG. 9, the inner peripheral side of the front surface 111a of the second ring portion 111 is not chamfered. If the upper end edge 111b of the taper shape is not formed, it becomes difficult for the deposit D to enter the gap g from the gap between the circumferential portion of the wafer W and the inner peripheral portion of the second ring portion 111. Thus, the adhesion amount of the deposit D adhering to the upper end edge 100b of the electrostatic chuck 13 can be further reduced. In the example shown in FIG. 9, however, chamfering required for processing is allowed. Here, the chamfering required for processing means providing a taper portion corresponding to about 1% to 2% of a width of the second ring portion 111 (i.e., a length from the inner peripheral end of the second ring portion 111 to the outer peripheral end thereof). That is, it is desirable that the inner peripheral surface and the top surface of the second ring portion 111 are formed to be at a right angle (chamfering is not performed), or a size of the taper-shaped upper end edge 111b is set to be equal to or less than 2% of the width of the second ring portion 111.

Further, to achieve the effect of the present exemplary embodiment, that is, the effect of suppressing the adhesion of the deposit D to the upper end edge 100b, a material of the edge ring 14 is not particularly limited. As mentioned above, the edge ring 14 may be made of, by way of non-limiting example, quartz, Si, SiC, or the like.

<Cleaning of Edge Ring>

In the present exemplary embodiment as described above, the groove 112 is formed on the front surface 110a of the first ring portion 110. Accordingly, in the plasma processing, the adhesion amount of the deposit Din the gap G to the front surface 110a is increased, so that the adhesion amount of the deposit D to the upper end edge 100b of the electrostatic chuck 13 is reduced. Now, cleaning of the front surface 110a to which the deposit D is attached will be explained.

The cleaning of the edge ring 14 is performed in the state that the plasma processing upon the wafer W is not being performed, that is, in the state that the wafer W is not placed on the placing table 11. To elaborate, after the plasma processing upon the wafer W is completed, the inside of the chamber 10 is decompressed to a required vacuum level by the exhaust device 54.

Then, a cleaning gas, for example, an oxygen gas is supplied from the gas source group 40 into the processing space S through the shower head 30. Further, the high frequency power HF for plasma formation is supplied to the lower electrode 12 by the first high frequency power supply 20 to excite the oxygen gas, so that oxygen plasma is formed. Since the electrostatic chuck 13 is made of, for example, ceramic, it has resistance against the oxygen plasma. Accordingly, only the deposit D attached to the front surface 110a is removed by being etched by the oxygen plasma.

In this case, since the temperature of the edge ring 14 is higher than the temperature of the electrostatic chuck 13, an adhesion strength of the deposit D to the front surface 110a is weak. Thus, the deposit D on the front surface 110a can be removed sufficiently through the cleaning of the oxygen plasma. Besides, since the edge ring 14 can be cleaned within the plasma processing apparatus 1, the throughput of the wafer processing can be improved, and the MTBC can be increased.

Furthermore, in the present exemplary embodiment, the first high frequency power supply 20 and the gas source group 40 constitute a cleaning device according to the present disclosure.

The plasma processing apparatus 1 according to the above-described exemplary embodiment is configured as the capacitively coupled plasma processing apparatus. However, the plasma processing apparatus to which the present disclosure is applied is not limited thereto. By way of example, the plasma processing apparatus may be an inductively coupled plasma processing apparatus. Regardless of the apparatus configuration of the plasma processing apparatus, the above-described effect can be obtained as long as the edge ring 14 of the present exemplary embodiment is used.

It should be noted that the above-described exemplary embodiment is illustrative in all aspects and is not anyway limiting. The above-described exemplary embodiment may be omitted, replaced and modified in various ways without departing from the scope and the spirit of claims.

According to the exemplary embodiment, it is possible to suppress the adhesion of the reaction product to the circumferential portion of the placing surface of the placing table on which the processing target object is placed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. An edge ring disposed on a placing table to surround a processing target object placed on a placing surface of the placing table, the edge ring comprising:
a first ring portion having a front surface located at a position lower than the placing surface; and
a second ring portion, provided at an outer side than the first ring portion in a diametrical direction thereof, having a front surface located at a position higher than the placing surface,
wherein the front surface of the first ring portion has an irregularity.

2. The edge ring of claim 1,
wherein the irregularity is formed by providing a groove on the front surface of the first ring portion.

3. The edge ring of claim 2,
wherein the groove is annularly formed on the front surface of the first ring portion.

4. The edge ring of claim 2,
wherein the groove has multiple grooves, and the multiple grooves are arranged in the diametrical direction of the first ring portion.

5. The edge ring of claim 2,
wherein a thickness of a portion of the first ring portion where the groove is provided is equal to or larger than 0.7 mm.

6. The edge ring of claim 5,
wherein the thickness of the portion of the first ring portion where the groove is provided is equal to or less than 0.8 mm.

7. The edge ring of claim 1,
wherein the irregularity is formed under the processing target object placed on the placing table.

8. A plasma processing apparatus configured to perform a plasma processing on a processing target object, the plasma processing apparatus comprising:
a chamber having therein a processing space in which plasma is formed;
a placing table provided within the chamber and configured to place the processing target object thereon; and
an edge ring disposed on the placing table to surround the processing target object placed on a placing surface of the placing table,
wherein the edge ring comprises:
a first ring portion having a front surface located at a position lower than the placing surface; and
a second ring portion, provided at an outer side than the first ring portion in a diametrical direction thereof, having a front surface located at a position higher than the placing surface, and
the front surface of the first ring portion has an irregularity.

9. The plasma processing apparatus of claim 8,
wherein the irregularity is formed by providing a groove on the front surface of the first ring portion.

10. The plasma processing apparatus of claim 9,
wherein the groove is annularly formed on the front surface of the first ring portion.

11. The plasma processing apparatus of claim 9,
wherein the groove has multiple grooves, and the multiple grooves are arranged in the diametrical direction of the first ring portion.

12. The plasma processing apparatus of claim 9,
wherein a thickness of a portion of the first ring portion where the groove is provided is in a range from 0.7 mm to 0.8 mm.

13. The plasma processing apparatus of claim 8,
wherein the irregularity is formed under the processing target object placed on the placing table.

14. The plasma processing apparatus of claim 8, further comprising:
a cleaning device configured to clean the edge ring; and
a controller configured to control the cleaning device to clean the edge ring in a state that the processing target object is not placed on the placing table.

15. The plasma processing apparatus of claim 14,
wherein the cleaning device cleans the edge ring by using plasma.
